(19) United States
(12) Patent Application Publication
(10) Pub. No.: US 2023/0373000 A1
(43) Pub. Date: Nov. 23, 2023

(54) Manufacturing of Workpieces Having Nanostructured Phases from Functionalized Powder Feedstocks

(71) Applicant: Forge Nano, Inc., Thornton, CO (US)

(72) Inventors: David King, Sudbury, MA (US); Arrelaine Dameron, Boulder, CO (US)

(21) Appl. No.: 18/363,834

(22) Filed: Aug. 2, 2023

Related U.S. Application Data
(63) Continuation of application No. 16/880,246, filed on May 21, 2020, now abandoned.
Application No. 16/880,246 is a continuation of application No. PCT/US2018/062271, filed on Nov. 21, 2018.
(60) Provisional application No. 62/589,663, filed on Nov. 22, 2017.

(51) Int. Cl. B22F 3/22; B33Y 70/00; B22F 1/17; B22F 1/054; B22F 1/16; B22F 1/18; B22F 1/102

(52) U.S. Cl. CPC B22F 3/225; B33Y 70/00; B22F 1/17; B22F 1/054; B22F 1/16; B22F 1/18; B22F 1/056; B22F 1/102; B33Y 80/00

(57) ABSTRACT

Nano-engineered materials for powder metallurgy and workpieces created using the materials. Workpieces include primary phase powders having nano-engineered partial or complete coatings and/or secondary phases adhered to interfaces of their constituent materials. Nano-engineered coatings are provided for metallic, polymeric and/or ceramic powder metallurgy feedstock powders to produce workpieces with superior performance and/or functional benefits, as are methods of manufacturing injection molding and additive manufacturing feedstock powders containing these coatings and additional respective functional benefits.

### CROSS-REFERENCE TO RELATED APPLICATIONS

This application is a continuation of International Application No. PCT/US2018/062271, filed Nov. 21, 2018, which claims the benefit of and priority to U.S. Provisional Application No. 62/589,663, filed Nov. 22, 2017, both of which are hereby incorporated by reference herein in their entireties.

### FIELD

The present technology generally relates to the field of Powder Metallurgy (PM). Particularly, the present technology relates to powders that are used as feedstocks for Injection Molding (IM), Additive Manufacturing (AM) and other powder-based fabrication systems, wherein the powders have nano-engineered partial or complete coatings and/or secondary phases adhered to interfaces of their constituent materials. More particularly, the present technology relates to nano-engineered coatings for metallic, polymeric and ceramic IM and AM feedstock powders to produce workpieces with superior performance and/or functional benefit, and methods of manufacturing IM and AM feedstock powders containing these coatings and additional respective functional benefits.

### BACKGROUND

The incorporation of particles from millimeter-scale down to nanometers in size is ubiquitous in end-use products. These particles are typically synthesized as powders from vapor, liquid or solid precursors, and produced in industrial-scale quantities in transformation processes in many states of matter, including gas, sub-critical liquid, super-critical fluid, solid, or plasma. Many synthesis processes have been used and optimized for decades, if not centuries, however these process optimization steps are typically carried out within each process, with little, if any, regard for how the particles are used, treated or even upgraded by the following step in a value chain. A significant percentage of the particles used across all industries can be enhanced by upgrading or post-treatment processes, that alter the surface properties without adversely affecting the bulk materials. Upgrading processes can result in a discrete shell, layer, film, or other coating, ranging from sub-nanometer to hundreds of micrometers in thickness, or an inter-diffused layer that is a homogenized region that incorporates a material, function, structure or other physical or chemical property derived from both the bulk and the surface compositions. Alternate processing steps may result in secondary phases adhered to primary particles. Coatings, or more broadly, secondary phases may comprise 0.0001 wt % (typically measured in parts per million) up to 50 wt %, and if preferable, tertiary, quaternary, and so on, phases (referred to hence forth as a secondary phase, which is understood to include the incorporation of additional sub-phases) may be incorporated to achieve a functional benefit in the end-use mixture or product. In the absence of a coating or secondary phase, adjacent particles may fuse, sinter, ripen or other analogous process when subject to a particular post-treatment, and the coating is sometimes engineered to function as a barrier that inhibits, retards, prevents or otherwise reduces the propensity for such a process to occur. Sometimes the secondary phase is engineered to enhance or otherwise alter the process in which particles are designed to fuse, sinter, ripen, either during a generic welding or joining process, or preferentially during a post-treatment. Alternatively, a post-treatment process can be used to remove a native surface through physical or chemical etching, reaction, conversion or other removal process. In most cases, if one post-treatment process can enhance the value of a particular product, multiple post-treatment process can also be expected to synergistically enhance performance, whether by similar processes comprising dissimilar materials, similar materials applied using dissimilar processes, or dissimilar materials applied using dissimilar processes. The field of metallurgy, and more broadly composite matrix formation, is ripe with examples of the benefits, and oftentimes criticality, of post-treatment processing, especially in the formation of high strength steels and metal alloys.

For example, a manufacturer of particles useful as a feedstock to an AM system, may optimize a high yield process for a product with a particular particle size or size distribution, allowing the manufacturer to sell one product at a high yield to many customers. However, when powders are deployed into heavily segmented marketplaces, such as batteries, pigments, catalysts, additives, AM feedstocks, etc., and can be sold as dry powders, slurries, suspensions or as granulated solids, for example, there is an emerging need for the customer to have more control over the size, type, format, composition and upgrading technology that is used, to allow the customer's products to be better optimized and tailored to end-use specifications. By way of examples, a conductive carbon product can be deployed in a battery, capacitor or a fuel cell, each of which can be further segmented by application or type of product; each may benefit from different sizes, surface areas and functional coatings, and it is rare that a materials manufacturer will have visibility to, or understand the complexities of, the impact of the manufacturers' process optimization efforts on the customers' end-use performance. Separately, from the AM perspective, there are many types of metal alloys that can be used for the production of metallic workpieces using an AM tool, but the specific size, shape, function and mechanical properties may vary widely by alloy and type of product that is being produced, thus severally limiting their practical application. Ultimately there is a value proposition for metal workpieces produced using an additive manufacturing process that can achieve the same mechanical properties of forged, injection molded, cast or otherwise machined metal parts, without having any drawbacks associated with these traditional methods.

### SUMMARY

One aspect of many embodiments of the invention relates to workpieces comprising a primary phase and a secondary phase, wherein primary phase powders have nano-engineered, partial or complete coatings, and/or secondary phases, adhered to interfaces of their constituent materials. Certain embodiments described herein provide nano-engineered coatings for metallic, polymeric and/or ceramic PM feedstock powders to produce workpieces with superior performance and/or functional benefits, and methods of manufacturing IM and AM feedstock powders containing these coatings and additional respective functional benefits.

In at least one embodiment, a workpiece which comprises a primary phase comprising at least one of a metal, metal alloy, ceramic, glass and polymer; and a secondary phase comprising at least one of a metal, metal alloy, ceramic, glass and polymer, wherein the secondary phase is chemically or physically adhered to the surface of the primary phase prior to the fabrication of the workpiece. In at least one embodiment, the primary phase is derived from a powdered feedstock configured for use in an additive manufacturing, a 3D printing, a binder jet printing, a laser melting, a plasma sintering, and injection molding, an extrusion-based, a cold spraying, or a subtractive manufacturing process.

In at least one embodiment, the primary phase has a characteristic grain size of up to about 500 μm. In at least one embodiment, the primary phase has a characteristic grain size between 10 nm and 100 μm. In at least one embodiment, the primary phase has a characteristic grain size between 100 nm and 10 μm. In at least one embodiment, the primary phase has a characteristic grain size of up to about 1 μm.

In at least one embodiment, the primary phase or the secondary phase is uniformly distributed throughout the workpiece.

In at least one embodiment, the workpiece comprises a plurality of volume elements. In at least one embodiment, one or more physical or mechanical properties of any two identically-sized, distinct volume elements of the workpiece deviate by no more than 10%, wherein the cube root of each volume element is no more than three times the median grain size of the primary phase of the workpiece. In at least one embodiment, one or more chemical or electrical properties of any two identically-sized, distinct volume elements of the workpiece deviate by no more than 10%, wherein the cube root of each volume element is no more than three times the median grain size of the primary phase of the workpiece. In at least one embodiment, the chemical composition of any two identically-sized, distinct volume elements of the workpiece deviate by no more than 10%, wherein the cube root of each volume element is no more than three times the median grain size of the primary phase of the workpiece.

In at least one embodiment, the secondary phase material is in the form of a coating covering at least 70% of the external surface area of the primary phase powder prior to the fabrication of the workpiece. In at least one embodiment, the coating is applied using one or more of a sol-gel, a microemulsion, a physical vapor, a chemical vapor, an atomic layer, a thermal decomposition, a chemical decomposition, or a supercritical fluid deposition process. In at least one embodiment, the secondary phase material remains i) adjacent to, ii) interspersed with, or iii) interfaced with grains of the primary phase material.

In at least one embodiment, the primary phase comprises titanium, aluminum, boron, chlorine, iron, chromium, cobalt, magnesium, molybdenum, tungsten, nickel, tin, tantalum, vanadium, yttrium, carbon, zinc, silicon or zirconium. In at least one embodiment, grains of the primary phase material are separated by a uniform distance ranging from 0.1 nm to 100 nm.

In at least one embodiment, the workpiece is manufactured using one or more of an additive manufacturing, a 3D printing, a binder jet printing, a laser melting, a plasma sintering, and injection molding, an extrusion-based, a cold spraying, or a subtractive manufacturing process.

In at least one embodiment, the secondary phase comprises an oxide, a nitride, a carbide, a boride, a halide, or an aluminide. In at least one embodiment, the secondary phase comprises one or more additional sub-phases.

In at least one embodiment, the composition of the secondary phase in the workpiece is different from the composition of the secondary phase of a starting powder prior to the fabrication of said workpiece. In at least one embodiment, the secondary phase composition is formed during the fabrication of said workpiece.

In at least one embodiment, the workpiece is configured for use (i.) in a nuclear application, (ii.) in an anode, anolyte, cathode, catholyte, electrolyte, current collector, stack member, electrode assembly, separator, membrane, or as a pack member of an electrochemical cell; (iii.) in a liquid-electrolyte comprising battery, a solid-electrolyte comprising battery, a capacitor, an electrolyzer, a liquid-electrolyte comprising fuel cell, or a solid-electrolyte comprising fuel cell; (iv.) as a structural or reinforcing member; (v.) as an armor or shielding member on a stationary or mobile device; (vi.) as a lightweighting means for a motive or mobility application.

In some embodiments, a workpiece of the present technology may comprise a primary phase comprising one or more of titanium metal, a titanium alloy, aluminum metal or an aluminum alloy, and the secondary phase comprises one or more of a metal oxide or a metal nitride.

In some embodiments, a workpiece of the present technology may comprise a primary phase comprising a stainless steel alloy, and the secondary phase comprises one or more of a metal oxide or a metal nitride.

In some embodiments, a workpiece of the present technology may comprise a primary phase comprising one or more of chromium metal, a chromium alloy, cobalt metal or a cobalt alloy, and the secondary phase comprises one or more of a metal oxide or a metal nitride.

In some embodiments, a workpiece of the present technology may comprise a primary phase comprising one or more of iron metal, an iron alloy or a ferrite material, and the secondary phase comprises one or more of a metal, a metal oxide or a metal nitride.

In some embodiments, a workpiece of the present technology may comprise a primary phase comprising magnesium or a magnesium alloy, and the secondary phase comprises one or more of a metal oxide or a metal nitride.

### BRIEF DESCRIPTION OF THE DRAWINGS

The details of one or more embodiments are set forth in the accompanying drawings and the description below. Other features, aspects, and advantages of the disclosure will become apparent from the description, the drawings, and the claims. In the drawings, like reference numerals are used throughout the various views to designate like components.

FIG. 1A is an embodiment of a particle having a geometrically simple primary phase and a secondary phase in the form of a geometrically simple and uniform coating. FIG. 1B is an embodiment of a particle having a geometrically complex primary phase and a secondary phase in the form of a geometrically simple and uniform coating. FIG. 1C is an embodiment of a particle having a geometrically simple primary phase and a secondary phase in the form of a geometrically complex discontinuous or particulate-based coating, which may be uniform in thickness across the external surface area. FIG. 1D is an embodiment of a particle having a geometrically complex primary phase and a secondary phase in the form of a geometrically complex discontinuous or particulate-based coating, which may further be non-uniform in thickness across the external surface area.

FIG. 2 depicts a simplified schematic of a workpiece of the present technology, with exploded views of the regional and local microstructures.

FIG. 3 depicts an exploded view of the local microstructure of a workpiece of an embodiment of the present technology, highlighting a uniform distribution of the primary and secondary phases.

FIG. 4A shows a geometrically simplified schematic of the local microstructure of a workpiece of an embodiment of the present technology, when the primary and secondary phases are of similar loadings. FIG. 4B shows a geometrically simplified schematic of the local microstructure of a workpiece of an embodiment of the present technology, where the loading ratio of the primary and secondary phases is high. FIG. 4C shows a geometrically simplified schematic of the local microstructure of a workpiece of an embodiment of the present technology, where the loading ratio of the primary and secondary phases is extremely high. FIG. 4D shows an alternate schematic of the local microstructure of a workpiece of an embodiment of the present technology, where the loading ratio of the primary and secondary phases is extremely high, and the secondary phase becomes distributed throughout the workpiece.

FIG. 5A depicts a cross-sectional image of the non-uniform microstructure of a conventional workpiece that does not incorporate a nano-engineered powder feedstock. FIG. 5B depicts a cross-sectional image of the uniform microstructure of a workpiece that incorporates the nano-engineered feedstock of the present technology.

FIG. 6 depicts a photographic image of a series of samples of annealed Ti-64 powders having various coating thicknesses of a metal oxide applied to the surfaces of the powder feedstock, demonstrating oxidation resistance (retained gray color) or lack of oxidation resistance (dark brown color).

It will be recognized that some or all of the figures are schematic representations for purposes of illustration. The figures are provided for the purpose of illustrating one or more embodiments with the explicit understanding that they will not be used to limit the scope or the meaning of the claims. The depiction of a particular height, length, width, relative sizing, and the like, are intended to serve as examples only, and are not intended to limit the scope of the present technology.

### DETAILED DESCRIPTION

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s).

Features may be described herein as part of the same or separate aspects or embodiments of the present technology for the purpose of clarity and a concise description. It will be appreciated by the skilled person that the scope of the present technology may include embodiments having combinations of all or some of the features described herein as part of the same or separate embodiments.

Various techniques and mechanisms of the present technology will sometimes be described in singular form for clarity. However, it should be noted that some embodiments include multiple iterations of a technique or multiple instantiations of a mechanism unless noted otherwise. In the following description, numerous specific details are set forth in order to provide a thorough understanding of the present technology. Particular example embodiments of the present technology may be implemented without some or all of these specific details. In other instances, well known process operations have not been described in detail in order not to unnecessarily obscure the present technology.

The following terms are used throughout and are as defined below.

As used herein and in the appended claims, singular articles such as “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of refereeing individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified. The expression “comprising” means “including, but not limited to.” Thus, other non-mentioned substances, additives, carriers, or steps may be present. Unless otherwise specified, “a” or “an” means one or more.

Unless otherwise indicated, all numbers expressing quantities of properties, parameters, conditions, and so forth, used in the specification and claims are to be understood as being modified in all instances by the term “about.” Accordingly, unless indicated to the contrary, the numerical parameters set forth in the following specification and attached claims are approximations. Any numerical parameter should at least be construed in light of the number reported significant digits and by applying ordinary rounding techniques. The term “about” when used before a numerical designation, e.g., temperature, time, amount, and concentration including range, indicates approximations which may vary by (+) or (−) 10%, 5% or 1%.

As will be understood by one of skill in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member.

Injection Molding (IM), Additive Manufacturing (AM) are together referred to herein as AM for simplicity.

Various embodiments of the present technology described herein relates to using a nano-structuring coating process that will add a homogeneous distribution of nano-sized grains onto powders used for higher performance additively manufactured workpieces and/or will result in a homogeneous distribution of nano sized grains in the completed product after AM is applied.

In one aspect, disclosed are nano-engineered coatings for metallic, polymeric and ceramic Injection M and AM feedstock powders to produce workpieces with superior performance and/or functional benefit, and methods of manufacturing IM and AM feedstock powders containing these coatings and additional respective functional benefits.

For a variety of reasons, each sector or industry has determined that the incorporation of coated particles into the end-use product provides enough value-add in the performance of the product that the cost associated with each coating process is justified. Vapor deposition techniques are sometimes used to deposit the coatings. Examples of vapor deposition techniques can include molecular layering (ML), chemical vapor deposition (CVD), physical vapor deposition (PVD), atomic layer deposition (ALD), molecular layer deposition (MLD), vapor phase epitaxy (VPE), atomic layer chemical vapor deposition (ALCVD), ion implantation or similar techniques. In each of these, coatings are formed by exposing the powder to reactive precursors, which react either in the vapor phase (in the case of CVD, for example) or at the surface of the powder particles (as in ALD and MLD). These processes can be augmented by the incorporation of plasma, pulsed or non-pulsed lasers, RF energy, and electrical arc or similar discharge techniques. Sometimes liquid-phase techniques are used to synthesize materials and/or deposit the coatings. Examples of liquid-phase techniques include, but are not limited to, sol-gel, co-precipitation, self-assembly, layer-by-layer or other techniques. Liquid-phase techniques share at least one commonality when producing powders: due to the energy intensiveness and cost of mixing, separating and drying materials synthesized or coated using liquid-phase techniques, greater efficiencies can be obtained by utilizing gas-solid unit operations. Additionally, typical AM feedstock powders are required to maintain a high degree of particle size uniformity and are typically sold as close to monodisperse as possible, as this assists in the uniformity of the printing process. Dry powders that undergo liquid-phase treatments may suffer from altered particle size distributions, agglomeration during separation/drying, or other drawbacks of the liquid-phase process that leads to an inferior workpiece. Another benefit of utilizing gas-solid unit operations is the ability to implement solid-state reaction technologies (e.g. annealing, calcining or other thermal treatment in a variety of controlled gaseous environments), in sequence with synthesis or coating steps. In one aspect, provided herein is a manufacturing system and strategy that allows for full control of all aspects of the production of targeted materials in one overarching scheme, and leads to the highest performance workpiece at the lowest possible cost.

Currently when workpieces or wrought parts are produced using conventional fabrication processes as small-volume orders, substantial cost premiums are inherent due to the custom-nature of these types of manufacturing runs. AM, also known as 3-D printing, can provide a mechanism for producing custom, short-run parts on a Just-In-Time or an on-demand basis (reducing cost barriers). However, the difference in mechanical or structural properties (particularly at high strain rates) cause today's AM-derived parts to exhibit properties that do not meet those of higher unit cost, conventional (wrought) counterparts. One embodiment of this disclosure relates to a cost-reduction strategy for workpiece manufacturing that uses a low-cost and high-throughput Atomic Layer Deposition (ALD) nanostructured coating process to engineer the grain size and structure of the finished workpiece, in order to precisely tailor the mechanical properties of AM-derived parts such that they are comparable to currently procured parts.

In one aspect, disclosed herein is a workpiece which includes a primary phase and a secondary phase. In some embodiments, the secondary phase may be included as a coating on the primary phase. In some embodiment, the secondary phase material is in the form of a coating covering at least 70% of the external surface area of the primary phase powder prior to the fabrication of the workpiece. This includes a coating covering about 75%, 80%, 85%, 90%, or 95% of the external surface area of the primary phase powder prior to the fabrication of the workpiece.

The primary phase may include one or more of a metal, metal alloy, ceramic, glass and polymer. The secondary phase may include one or more of a metal, metal alloy, ceramic, glass and polymer. In some embodiments, the secondary phase is chemically or physically adhered to the surface of the primary phase prior to the fabrication of the workpiece. In at least one embodiment, the primary phase is derived from a powdered feedstock configured for use in an additive manufacturing, a 3D printing, a binder jet printing, a laser melting, a plasma sintering, and injection molding, an extrusion-based, a cold spraying, or a subtractive manufacturing process.

The characteristic grain size of the primary phase may depend on various factors such as the desired workpiece characteristics and the particular end-use application. In exemplary embodiments, the primary phase may have a characteristic grain size of up to about 1000 μm. In at least one embodiment, the primary phase may have a characteristic grain size of up to about 500 μm, including from about 5 nm to about 500 μm, from about 10 nm to about 100 μm, from about 1 nm to about 50 μm, or from about 5 μm to about 20 μm, and ranges between any two of these values or less than any one of these values. In at least one embodiment, the primary phase has a characteristic grain size between 10 nm and 100 μm. In at least one embodiment, the primary phase has a characteristic grain size between 100 nm and 10 μm. In at least one embodiment, the primary phase has a characteristic grain size of up to about 1 μm.

The workpiece of the present technology may include a plurality of volume elements. In some embodiments, one or more physical or mechanical properties of any two identically-sized, distinct volume elements of the workpiece deviate by no more than 10%, wherein the cube root of each volume element is no more than three times the median grain size of the primary phase of the workpiece. In other embodiments, one or more chemical or electrical properties of any two identically-sized, distinct volume elements of the workpiece deviate by no more than 10%, wherein the cube root of each volume element is no more than three times the median grain size of the primary phase of the workpiece. In yet other embodiments, the chemical composition of any two identically-sized, distinct volume elements of the workpiece deviate by no more than 10%, wherein the cube root of each volume element is no more than three times the median grain size of the primary phase of the workpiece.

Suitable primary phase materials are described herein. In at least one embodiment, the primary phase comprises titanium, aluminum, boron, chlorine, iron, chromium, cobalt, magnesium, molybdenum, tungsten, nickel, tin, tantalum, vanadium, yttrium, carbon, zinc, silicon or zirconium. In at least one embodiment, grains of the primary phase material are separated by a uniform distance ranging from 0.1 nm to 100 nm, including from about 1 nm to about 50 μm, from about 10 nm to about 25 μm, or from about 1 μm to about 10 μm, and ranges between any two of these values or less than any one of these values.

Suitable secondary phase materials are described herein. In at least one embodiment, the secondary phase comprises an oxide, a nitride, a carbide, a boride, a halide, or an aluminide. In some embodiments, the secondary phase comprises one or more additional sub-phases. In some embodiments, the composition of the secondary phase in the workpiece is different from the composition of the secondary phase of a starting powder prior to the fabrication of said workpiece. In some embodiments, the secondary phase composition is formed during the fabrication of said workpiece.

Suitable methods for applying or depositing the secondary phase materials on to the primary phase materials are described herein. In some embodiments, the secondary phase or coating is applied using one or more of a sol-gel, a microemulsion, a physical vapor, a chemical vapor, an atomic layer, a thermal decomposition, a chemical decomposition, or a supercritical fluid deposition process. In at least one embodiment, the secondary phase material remains i) adjacent to, ii) interspersed with, or iii) interfaced with grains of the primary phase material.

Suitable methods for manufacturing a workpiece of the present technology are described herein. In some embodiments, the workpiece is manufactured using one or more of an additive manufacturing, a 3D printing, a binder jet printing, a laser melting, a plasma sintering, and injection molding, an extrusion-based, a cold spraying, or a subtractive manufacturing process.

In some embodiments, the secondary phase is designed to improve joining, welding or combining processes to form solid workpieces comprising typically non-weldable or non-joinable metals or metal alloys, and difficult to weld or join metals or metal alloys. The term weldability is often defined qualitatively rather than quantitatively, such as by ISO standard 581-1980, which recites “Metallic material is considered to be susceptible to welding to an established extent with given processes and for given purposes when welding provides metal integrity by a corresponding technological process for welded parts to meet technical requirements as to their own qualities as well as to their influence on a structure they form.” In one aspect, the present technology provides a secondary phase that improves the susceptibility to welding and achieving the technical requirements and qualities of finished workpieces produced using any of the processes described herein.

In other embodiments, the nano-engineered powdered feedstock is designed to enable sintering or joining of typically difficult-to-sinter ceramics and difficult to join glassy materials. The sintering temperature of ceramics can be estimated to be approximately two-thirds of the melting temperature of the ceramic material. Ceramics with very high melting temperatures (e.g. carbide materials, of which tungsten carbide and silicon carbide are representative examples) are difficult to sinter or join with other similar or dissimilar materials. In another aspect, the present technology provides a secondary phase that improves the susceptibility to sintering and achieving the technical requirements and qualities of finished workpieces produced using any of the processes described herein. Also known as a sintering aid, a uniform coating of a specific secondary phase (or combinations of additional phases as provided for previously) will maximize the degree of sintering at the lowest net energy input to achieve the same functional performance without the presence of specific secondary phases. Particulate-derived secondary phases are commonly used as sintering aids, however prior art does not teach that particular coatings of uniform, nanoscale materials to the surfaces of the materials to be sintered can achieve specific functional benefits to net shaping benefits, grain size/structure and/or mechanical properties, particularly when assembled into workpieces using one of the processes described herein. 3D printed ceramics, for example, would be difficult to produce using the standard particulate-based secondary phase approach to sintering aids used in the prior art. The uniform distribution and homogeneity of said secondary phase would be inconsistent on a per-particle basis, and also on a per-layer basis for workpieces constructed through a powder-based layer-by-layer additive manufacturing process. The technology described herein aims to overcome the insurmountable difficulties and property limitations of additively manufactured workpieces in the prior art, through the incorporation of highly uniform secondary phases onto primary particulate phases, such that the uniformity of each layer will be largely identical to other layers in the Z-direction throughout the workpiece. The uniform and homogeneous distribution of said secondary phase (or phases) will minimize the net energy required both to fabricate each workpiece to an as-built state, and to post-process each workpiece into a finished state. The energy savings typically exceed 10%, oftentimes 25%, sometimes 50%, and in certain cases and for certain materials, exceeds 60%. This dramatically reduces the net costs of producing additively-manufactured ceramics of equivalent quality as those fabricated using alternative and/or more conventional manufacturing processes.

In some embodiments, the nano-engineered feedstock is designed to enable the fusion, polymerization or joining of polymeric materials (as the primary or secondary phase) with poor joining properties. A term Rheological Weldability has been developed as an attempt to quantify the criterion to successfully weld or join polymeric materials to interfaces. Interfacial mechanics and the respective surface tension of the constituent materials, including the molten polymeric material, plays a role, as does the activation energy of the polymeric material. The incorporation of secondary phases of polymers having a lower activation energy or a lower viscosity at desirable welding conditions will improve the overall joining or rheological welding properties of polymeric materials. In some cases, the secondary phases comprise a glassy, ceramic or metallic material, which can create one or more additional functional benefits to the manufactured parts having a primary phase that comprises a polymeric material. In one aspect, the present technology provides a way to facilitate the synthesis of polymeric workpieces that are comprised of block co-polymers, as a simpler pathway that either a) fabricating a bulk block co-polymer via a conventional injection molding, casting or extrusion process where two discrete polymeric materials (that comprise the block co-polymer material) are administered into the fabrication system simultaneously; or b) are built in a layer-by-layer system via alternating steps of providing a layer comprising a first polymeric material, followed by a layer comprising a second polymeric material, wherein the first and second materials represent the final block co-polymer material. This latter approach would be most useful when the layer thickness, effectively corresponding to the molecular weight of each individual polymer, benefits from being large relative to the molecular scale, or when it is desirable that the ratio between the first and second phases are intended to approach unity.

For manufacturing purposes, it is oftentimes desirable to have a lower cost polymeric material comprise the large majority of a polymeric system and utilize a small loading of a secondary phase to create a block co-polymer that serves as a means of maintaining a high degree of adhesion amongst the localized interfaces. Rather than requiring a highly uniform cross-linking of polymeric chains uniformly throughout a substantial portion of the polymeric workpiece to achieve appropriate mechanical properties, the invention described herein benefits from enabling a smaller portion of the polymeric workpiece to be joined or welded through the formation of homogeneous block co-polymer interfaces that unexpectedly provided sufficient mechanical strength when uniformly distributed throughout the finished workpiece. Furthermore, it has been found that by adding a secondary phase that comprises a ceramic, glassy or metallic substance could further improve mechanical strength or add other electrical, thermal, optical or chemical benefits to the finished workpiece without detracting from other beneficial properties of the workpiece that was fabricated without said ceramic, glassy or metallic substances. A characteristic example is the incorporation of thermally-conductive ceramic layers such as aluminum nitride or boron nitride, or secondary phases comprising high thermal conductivity metals such as copper or aluminum. The ability to modulate the degree of interfacial wetting by using particular coating materials, with or without adhesion or linkage promoters as is beneficial, was shown to be able to significantly increase the thermal conductivity of workpieces having a primary phase that comprises a lightweight polymer. The homogeneous distribution of secondary phases that are applied to feedstock particles as coatings, which would all be in direct contact when administered into the layer-by-layer manufacturing system, allows for an increase in target properties or performance at loadings that are less than the percolation threshold for the bulk workpiece, due to a localized loading that exceeds the percolation threshold in the immediate vicinity of the secondary phases. This 2D or 3D network of secondary phases provides unexpected benefits to additively manufactured workpieces, and one skilled in the art can appreciate that this example of a polymeric material as a primary phase is exemplary only and extends to all features and conditions where a percolation threshold is required to observe a change in bulk properties. In some embodiments, the workpieces of the present technology, the primary phase or the secondary phase are uniformly distributed throughout the workpiece.

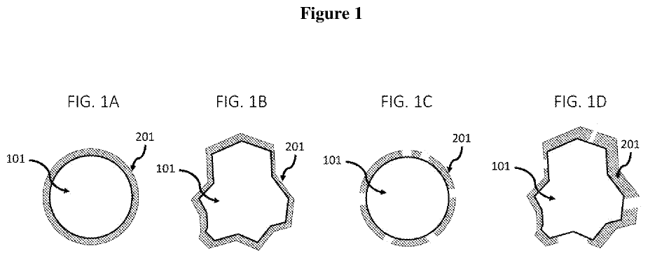

In FIG. 1, four general embodiments of materials (selected from a wider array of available embodiments) that are formed into the primary and secondary phases of a workpiece of the present technology are shown. The geometry of a powdered feedstock 101 may be described as ‘geometrically simple’, which in the case of a spheroid may have a sphericity of greater than 80%, 85%, 90% or 95%. One of ordinary skill in the art of AM understands the value of using a spherical powdered feedstock, which may have been intentionally spheroidized. However, the workpieces of the present technology are not limited to such geometrically simple powder types (as depicted in FIG. 1A and FIG. 1C), but also include powders with angular, rough, jagged or other irregular descriptive term or feature as depicted in FIG. 1B and FIG. 1D. A secondary phase of a workpiece of the present technology may be derived from secondary phase material 201, depicted in FIG. 1A and FIG. 1B as continuous, uniform coatings; FIG. 1C as discontinuous, uniform coatings; and FIG. 1D as discontinuous, non-uniform coatings. A secondary phase material 201 may be derived from the incorporation of secondary phase material particles affixed to or adhered to powdered feedstock 101. For simplicity, FIG. 1 only depicts a secondary phase, however in some embodiments, a secondary phase further includes a tertiary phase, a quaternary phase, or more generally described as one or more sub-phases, which may be in the form of coatings, particles, layers, lamellae, scales, or shells, amongst others, which all become part of a complex secondary phase of a fabricated workpiece of the present technology.

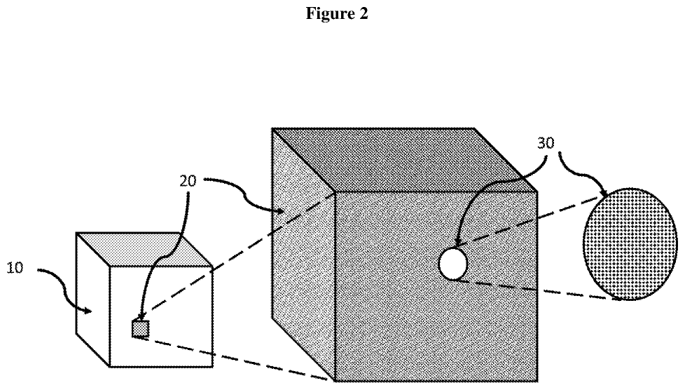

FIG. 2 depicts workpiece 10, an example of a workpiece of the present technology. Workpiece 10 comprises many sub-elements, depicted herein as regional volume element 20, each of which also comprises many sub-elements, depicted as microstructure element 30. In one aspect, the present technology allows for maximizing the dispersion and/or homogeneous distribution of a secondary phase amongst a primary phase within a fabricated workpiece, where the uniformity of the application of the secondary phase material onto the primary phase powdered feedstock is maintained throughout the workpiece fabrication process. An idealized embodiment is depicted in FIG. 2; however, it has been observed that two arbitrary regional volume elements of a workpiece fabricated using uniform process conditions result in mostly uniform sub-features and microstructure elements. One of ordinary skill in the art would understand that uniform process conditions may not be experienced at the edges of workpieces or other regions in which non-steady state process conditions are experienced. By mostly uniform, it is intended to always represent at most 20% a variation across equivalent-volume elements, usually less than 15% variation, oftentimes less than 10% variation, sometimes less than 5% variation, and in some instances less than 3% variation. Furthermore, this typically also holds true for similarly-sized cross-sectional slices derived from two distinct identically-sized volume elements processed using identical conditions. The uniformity of the application of the secondary phase material onto the primary phase powdered feedstock is a large factor in determining the homogeneity of the phase distribution in a finished workpiece of the present technology.

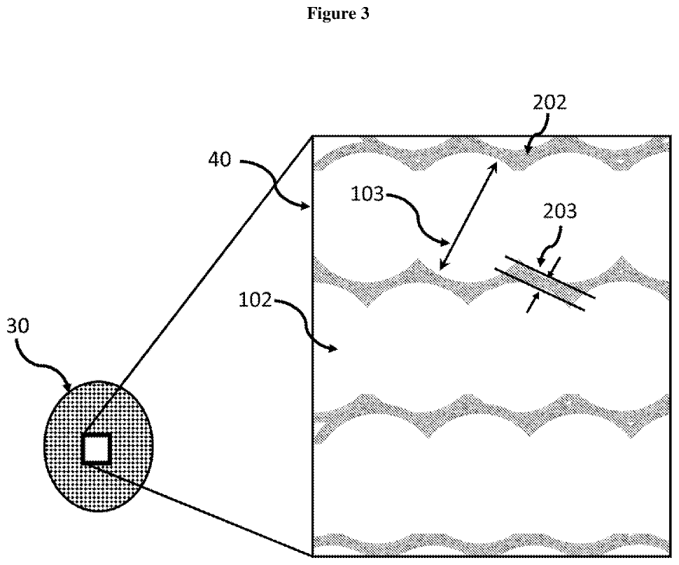

FIG. 3 depicts microstructure section 40, a further exploded view of microstructure element 30 (an element of regional volume element 20 and workpiece 10 of the present technology), showing a simplistic version of a phase segregation along one dimension. Microstructure section 40 comprises a primary phase 102, derived from powdered feedstock 101, and a secondary phase 202, derived from secondary phase material 201. In this depiction, secondary phase 202 is segregated from primary phase material 102, where primary phase material 102 comprises a primary grain size 103. Primary grain size 103 may be similar to the particle size of powdered feedstock 101, may be a fraction thereof, or may be a multiple thereof, but ultimately is dependent on the process parameters used to fabricate workpiece 10. Furthermore, the presence of secondary phase material 201 (and its associated composition, dimensions, etc.) may also directly impact the dimensionality of primary grain size 103. Said differently, a workpiece 10 derived from powdered feedstock 101 without the presence of a minimum critical quantity of secondary phase material 201 will result in a different (larger) primary grain size 103, relative to a workpiece 10 derived from a powdered feedstock 101 having a minimum critical quantity of secondary phase material 201. Primary grain size 103 is depicted as a single measurement point for simplicity, however one of ordinary skill in the art would appreciate that a numerical interpretation of a grain dimension may be a mean or median of a distribution of sizes. Similarly, FIG. 3 also depicts a simplified rendering of a grain boundary 203, which further may have a characteristic length scale that provides a separation between primary grains. As it is difficult to maintain or pin the secondary phase explicitly and permanently between each individual grain, the schematic of 203 is intended to represent a global phenomenon that is exploited due to the uniform application of secondary phase material 201 onto powdered feedstock 101. Similarly, secondary phase compositions and critical parameters are stochastic and distributional in nature, may be more prevalent in void spaces between powdered feedstock 101 prior to fabrication of workpiece 10, and are dependent on loading ratios, feedstock particle sizes, the geometric simplicity of powdered feedstock 101, amongst others. Ultimately, due to the difficulty in applying global fabrication parameters to each individual microstructure section 40, it was unanticipated that the global uniformity of the effects of secondary phase material 201 resulted in generally uniform outcomes in terms of the electrical, physical, mechanical, chemical, compositional properties of workpiece 10 of the present technology. This has not yet been predicted using modern theories of powder metallurgy, particularly when secondary phase material 201 is applied to powdered feedstock 101 at the Angstrom or nanometer length scale (typically less than 30 nanometers in length scale).

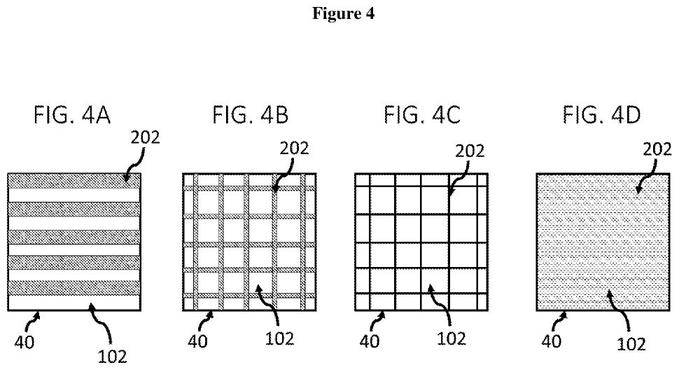

FIG. 4 depicts alternate embodiments of microstructure section 40 comprising primary phase material 102 and a secondary phase 202. FIG. 4A depicts a rare instance in which the loading ratios between 102 and 202 are similar, and a phase segregation is favored to occur. Even still, this type of segregation is typically only experienced in AM or layer-by-layer build processes, versus bulk IM or other conventional PM process. In order for such a pattern to form in such a one-dimensional direction in such a cross-section during an AM process, the interplay between the build process as well as the interactions between the powdered feedstock 101 and secondary phase material 201 must be right. If powdered feedstock 101 is more susceptible to melting during the build process than secondary phase material 201, and the surface energy differences between the two materials and phases is such that phase segregation is favorable, such a one-dimensional cross-sectional microstructure is achievable.

FIG. 4B depicts a more common instance for microstructure section 40, albeit still idealized as a geometrically-simple repeating unit (spheroids may be supplanted for the squares depicted in FIG. 4B). Such a two-dimensional patterning and/or repeating unit of such a cross-section (corresponding to a 3D repeating unit in a volume element). Again, a simplified primary grain size 103 is shown here, but is not intended to limit the invention to such an idealized, exactly identical grain size, but rather represent a mean or median grain size distribution. FIG. 4C depicts a similar schematic representation for microstructure section 40 as that shown in FIG. 4B, however the difference in attaining the two is based on the starting ratios of powdered feedstock 101 to secondary phase material 201 (i.e. diminishing line thickness corresponds to an increase in ratio of 101:201 in the workpiece).

FIG. 4D depicts a different type of microstructure section 40 layout, one in which the primary phases can become linked together across the secondary phase, which no longer takes the shape of a coating or shell, but rather a distribution of discontinuous secondary phase materials, or conversely, one in which the secondary phase becomes uniformly distributed throughout workpiece 10. In practice, it has been observed that there is minimal difference between the idealized schematic representation in FIG. 4C and that of FIG. 4D, when secondary phase material 201 is applied in the form of a surface coating onto powdered feedstock 101, due to the homogeneous distribution of secondary phase 202. This is particularly true when secondary phase material 201 can be described as having a length scale of less than 30 nanometers. If secondary phase material 201 begins as discrete particles affixed to the surfaces of powdered feedstock 101, it is difficult to produce microstructure section 40 as depicted by FIG. 4D due to i) the relatively wide particle size distribution inherent to powders having a mean particle diameter of 30 nanometers (such powders are typically aggregated chains of particles); and ii) the inability to produce well-mixed samples having such small particle sizes. The schematic representations depicted by FIG. 4C and FIG. 4D are the anticipated results based upon using exemplary embodiments of the present technology.

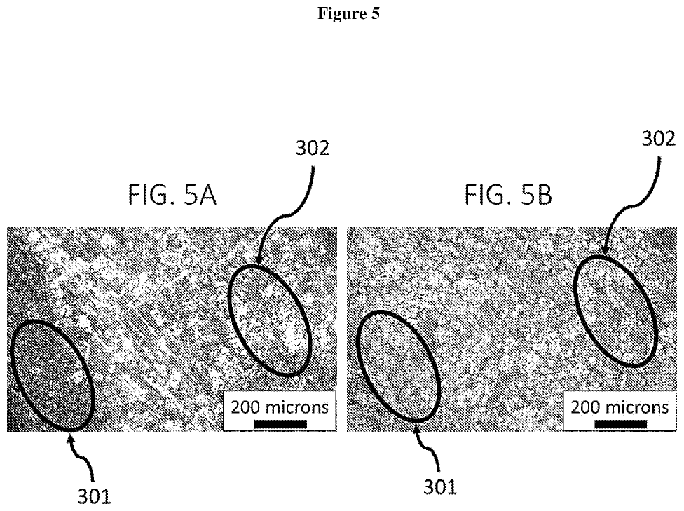

FIG. 5A shows a cross-sectional micrograph cut from a workpiece fabricated from 316L stainless steel powdered feedstocks that did not have a secondary phase material 201. Based on the highlighted regions identified as 301 and 302, the light and dark regions depict areas with significant non-uniformity. Alternatively, FIG. 5B shows a cross-sectional micrograph cut from a workpiece fabricated from 316L stainless steel powdered feedstocks that did have a secondary phase material 201 applied in the form of a coating of less than 30 nanometers, here aluminum oxide as a representative material that has generated unexpectedly positive results at such thicknesses. Again, regions 301 and 302 are highlighted (using the same size scales, cross-sectioning methods and fabrication parameters as the FIG. 5A workpiece), showing highly uniform areas throughout the distinct volume elements and regions.

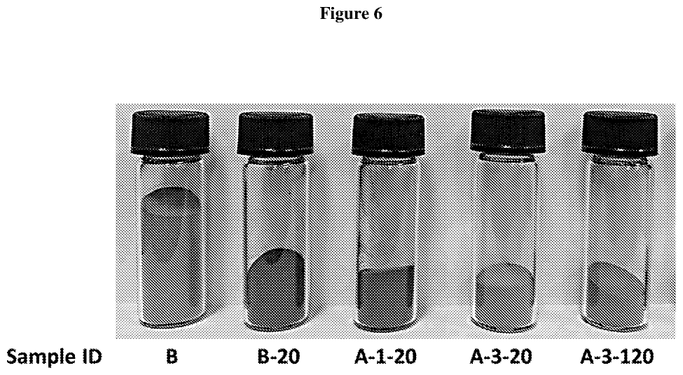

FIG. 6 shows photographic images of uncoated and coated powdered titanium alloy (Ti-64) feedstock powders (101). Samples labeled as “B” indicate a bare substrate with no secondary phase material coating applied; samples labeled as “A” indicate an aluminum oxide based secondary phase material coating applied (201) using an atomic layer deposition technique {“A-1”=1 nm; “A-3”=3 nm}. Table 1 describes the conditions for each sample. Sample “B-0-0” is a purely gray powder, which turned to a dark brown color when annealed at 450° C. for 20 hours (Sample “B-0-20”) due to the formation of a thermally-grown oxide layer. Sample “A-1-20” was coated with a 1 nm coating of aluminum oxide and annealed under the same conditions. This ultra-thin coating was not sufficient to prevent oxidation, and also resulted in a dark brown color. However, with the application of a 3 nm alumina layer, a purely gray powder resulted when annealing at 450° C. for the same 20-hour duration (Sample “A-3-20”). Sample “A-3-120” is shown (annealing at 450° C. for 120 hours) as having a slightly darker gray coloring, which is an indication that a slight amount of oxidation had occurred over the longer annealing time.

TABLE 1
Uncoated and Coated Ti-64 powders after annealing at 450° C.

| Sample ID | Description |
|---|---|
| B-0-0 | Bare Ti-64 powders used for Additive Manufacturing |
| B-0-20 | Bare Ti-64 powders annealed in air at 450° C. for 20 hours |
| A-1-20 | 1 nm Al₂O₃-coated Ti-64 powders annealed in air at 450° C. |
| | for 20 hours |
| A-3-20 | 3 nm Al₂O₃-coated Ti-64 powders annealed in air at 450° C. |
| | for 20 hours |
| A-3-120 | 3 nm Al₂O₃-coated Ti-64 powders annealed in air at 450° C. |
| | for 120 hours |

Common powder alloys used in the 3D printing of metals include stainless steel, maraging steel, other steels, cobalt chromium, inconel, aluminum alloys and titanium (and alloys), amongst others. Powder bed fusion, direct energy deposition and binder jetting are the primary methods used to additively manufacture components. Laser powder bed fusion is the most mature and well researched metal printing technology and is representative of ˜90% of the metal AM market. All powder bed fusion processes (e.g. Selective Laser Melting or SLM) involve the spreading of the powder material over previous layers. The key attributes of the SLM process include high resolution and the ability to reach a high density without post processing, and it can be easily customized to build any modestly sized part from a 3D drawing generated in a CAD program. A second software program divides the drawing into several “slices” of a predetermined thickness. Powder is first deposited in the build chamber and smoothed by a rake. A high-power laser beam then scans the powder bed in the necessary pattern to build the desired cross-section. The platform is subsequently lowered by the predetermined layer thickness and the process continues until the component is complete. The dry powder rheology of the AM feedstock material plays a large role in both the AM process and the uniformity and quality of the finished part. Near-full density is achieved by SLM, but because of the high heat input, loss of alloying elements, residual stress, and thermal distortion are possible consequences that need to be addressed through process parameter control and feedstock powder alloy adjustments. Ultimately, there are more than 200 process variables that can affect the final microstructure in laser powder bed additive manufacturing. Of those, about four variables have the largest effect on core properties and printability of AM workpieces: laser power, speed, hatch spacing and layer thickness. The ALD process, materials and loadings can unexpectedly change the properties of the AM workpieces rather dramatically, and the alignment of an optimized AM process using an optimized ALD-enabled AM feedstock powder has led to the ability to construct metallic, ceramic and polymeric workpieces with substantially improved properties. For the case of metallic AM processes, finished workpieces are shown to be capable of having mechanical properties that meet or exceed those of wrought counterparts, over a wide range of use conditions. In some cases, the use of ALD-enabled AM feedstock powder can reduce or eliminate the need for post-treatments that are required for AM workpieces that are produced using feedstock powders without ALD nanostructured coatings.

Smaller grains mean more grain boundaries, and as such, an increase in small grain boundaries increases the strength of a metal in accordance with the Hall-Petch effect:

$${σ}_{y} = {σ}_{0} + \frac{{k}_{y}}{\sqrt{d}} \qquad ( 1 )$$

where σ_{y} is the yield stress, σₒ is a materials constant for the starting stress for dislocation movement (or the resistance of the lattice to dislocation motion), k_{y} is the strengthening coefficient (a constant specific to each material), and d is the average grain diameter. Grain boundaries are barriers to dislocation motion; it has been observed experimentally that the microstructure with the highest yield strength is a grain size of about 10 nm. AM feedstock powders cannot be produced and used as nanopowders with an expectation of attaining sufficient flowability to form dense parts. The only way to produce engineering materials with this ideal grain size is by using thin film techniques such as ALD. Therefore, an embodiment of this approach allows for the application of uniform, homogeneous layers of up to 5 nm thick onto feedstock powders, to form 10 nm grains between adjacent particles. In some embodiments, the workpiece grains of the primary phase material are separated by a uniform distance ranging from 0.5 nm to 20 nm, 1 nm to 15 nm, 2 nm to 5 nm, or any other minimum and maximum range that is proportional to a characteristic length scale of the secondary phase material.

One commonality of gas-phase processing systems for producing or encapsulating powders is the need for the chemical reactant precursors to be volatile or otherwise able to be vaporized. Significant efforts have been undertaken over the past decades to increase the number and types of vaporizable precursors that can be available for such systems. Potential vaporizable precursors may include a compound selected from the group consisting of aluminum sec-butoxide, aluminum tribromide, aluminum trichloride, diethylaluminum ethoxide, dimethylaluminum isopropoxide, tris(ethylmethylamido)aluminum, tris(dimethylamido)aluminum, triethylaluminum, triisobutylaluminum, trimethylaluminum, tris(diethylamido)aluminum, tris(ethylmethylamido)aluminum, trimethylantimony(III), triethylantimony(III), triphenylantimony(III), tris(dimethylamido)antimony(III), trimethylarsine, triphenylarsine, triphenylarsine oxide, barium bis(2,2,6,6-tetramethyl-3,5-heptanedionate) hydrate, barium nitrate, bis(pentamethylcyclopentadienyl)barium tetrahydrofuran, bis(triisopropylcyclopentadienyl)barium tetrahydrofuran, bis(acetate-O)triphenylbismuth(V), triphenylbismuth, tris(2-methoxyphenyl)bismuthine, diborane, trimethylboron, triethylboron, triisopropylboroate, triphenylborane, tris(pentafluorophenyl)borane, cadmium acetylacetonate, calcium bis(2,2,6,6-tetramethyl-3,5-heptanedionate), carbon tetrabromide, carbon tetrachloride, cerium(III) trifluoroacetylacetonate, tetrakis(2,2,6,6-tetramethyl-3,5-heptanedionat)cerium(IV), tris(cyclopentadienyl)cerium(III), tris(isopropylcyclopentadienyl)cerium(III), tris(1,2,3,4-tetramethyl-2,4-cyclopentadienyl)cerium(III), bis(cyclopentadienyl)chromium(II), bis(pentamethylcyclopentadienyl)chromium(II), chromium(III) tris(2,2,6,6-tetramethyl-3,5-heptanedionate), chromium(II) chloride, chromium(III) chloride, chromium(II) carbonyl, chromium(III) carbonyl, cyclopentadienyl(II)chromium carbonyl, bis(cyclopentadienyl)cobalt(II), bis(ethylcyclopentadienyl)cobalt(II), bis(pentamethylcyclopentadienyl)cobalt(II), tribis(N,N′-diisopropylacetaminato)cobalt(II), dicarbonyl(cyclopentadienyl)cobalt(III), cyclopentadienylcobalt(II) carbonyl, copper bis(6,6,7,7,8,8,8-heptafluoro-2,2-dimethyl-3,5-octanedionate, copper bis(2,2,6,6-tetramethyl-3,5-heptanedionate, (N,N′-diisopropylacetaminato)copper(II), tris(2,2,6,6-tetramethyl-3,5-heptanedionato)dysprosium(III), tris(isopropylcyclopentadienyl)dysprosium(III), erbium(III) tris(2,2,6,6-tetramethyl-3,5-heptanedionate), tris(butylcyclopentadienyl)erbium(III), tris(N,N-bis(trimethylsilyl)amide)europium(III), tris(tetramethylcyclopentadienyl)europium(III), nitrogen trifluoride, tris(N,N-bis(trimethylsilyl)amide)gadolinium(III), tris(cyclopentadienyl)gadolinium(III), tris(tetramethylcyclopentadienyl)gadolinium(III), gallium tribromide, gallium trichloride, triethylgallium, triisopropylgallium, trimethylgallium, tris(dimethylamido)gallium, tri-tert-butylgallium, digermane, germane, tetramethylgermanium, germanium(IV) fluoride, germanium(IV) chloride, hexaethyldigermanium(IV), hexaphenyldigermanium(IV), tributylgermanium hydride, triphenylgermanium hydride, dimethyl(acetylacetonate)gold(III), dimethyl(trifluoroacetylacetonate)gold(III), hafnium (IV) chloride, hafnium (IV) tert-butoxide, tetrakis(diethylamido)hafnium (IV), tetrakis(dimethylamido)hafnium (IV), tetrakis(ethylmethylamido)hafnium (IV), bis(tert-butylcyclopentadienyl)dimethylhafnium(IV), bis(methyl-n-cyclopentadienyl)dimethylhafnium, bis(trimethylsilyl)amidohafnium(IV) chloride, dimethylbis(cyclopentadienyl)hafnium(IV), hafnium isopropoxide, tris(N,N-bis(trimethylsilyl)amide)holmium(III), indium trichloride, indium(I) iodide, indium acetylacetonate, triethylindium, tris(dimethylamido)indium, tris(diethylamido)indium, tris(cyclopentadienyl)indium, 1,5-cyclooctadiene(acetylacetonato)iridium(I), 1,5-cyclooctadiene(hexafluoroacetylacetonato)iridium(I), 1-ethylcyclopentadienyl-1,3-cyclohexadieneiridium(I), (methylcyclopentadienyl)(1,5-cyclooctadiene)iridium(I), bis(N,N′-di-tert-butylacetamidinato)iron (II), bis(pentamethylcyclopentadienyl)iron(II), ferrocene, 1,1′-diethylferrocene, iron pentacarbonyl, iron(III tris(2,2,6,6-tetramethyl-3,5-heptanedionate), tris(N,N-Di-tert-butylacetamidinato)lanthanum (III), lanthanum(III) isopropoxide, tris(N,N-bis(trimethylsilyl)amide)lanthanum(III), tris(cyclopentadienyl)lanthanum(III), tris(tetramethylcyclopentadienyl)lanthanum(III), tetraethyllead, tetramethyllead, tetraphenyllead, tithium t-butoxide, lithium trimethylsilylamide, lithium (2,2,6,6-tetramethyl-3,5-heptanedionate), tris(N,N-diisopropylacetamidinato)lutetium(III), lutetium(III) tris(2,2,6,6-tetramethyl-3,5-heptanedionate), bis(cyclopentadienyl)magnesium(II), bis(pentamethylcyclopentadienyl)magnesium(II), bis(pentaethylcyclopentadienyl)magnesium(II), bis(cyclopentadienyl)manganese(II), bis(N,N-diisopropylpentylamidinato)manganese(II), bis(ethylcyclopentadienyl)manganese(II), bis(pentamethylcyclopentadienyl)manganese(II), bis(isopropylcyclopentadienyl)manganese(II), cyclopentadienylmanganese tricarbonyl, manganese carbonyl, methylcyclopentadienylmanganese tricarbonyl, manganese tris(2,2,6,6-tetramethyl-3,5-heptanedionate), molybdenum hexacarbonyl, molybdenum (V) chloride, molybdenum (VI) fluoride, bis(cyclopentadienyl)molybdenum(IV) dichloride, cyclopentadienylmolybdenum(II) tricarbonyl, propylcyclopentadienylmolybdenum(I) tricarbonyl, tris(N,N-bis(trimethylsilyl)amide)neodymium(III), bis(methylcyclopentadienyl)nickel(II), allyl(cyclopentadienyl)nickel(II), bis(cyclopentadienyl)nickel(II), bis(ethylcyclopentadienyl)nickel(II), bis(triphenylphosphine)nickel(II) dichloride, nickel(II) bis(2,2,6,6-tetramethyl-3,5-heptanedionate), bis(cyclopentadienyl)niobium(IV) dichloride, niobium(V) chloride, niobium(V) isopropoxide, niobium(V) ethoxide, N,N-dimethylhydrazine, ammonia, hydrazine, ammonium fluoride, azidotrimethylsilane, triosmium dodecacarbonyl, allyl(cyclopentadienyl)palladium(II), palladium(II) hexafluoroacetylacetonate, bis(2,2,6,6-tetramethyl-3,5-heptanedionato)palladium(II), phosphine, tert-butylphosphine, tris(trimethylsilyl)phosphine, phosphorous oxychloride, triethylphosphate, trimethylphosphate, methylcyclopentadienyl(trimethyl)platinum (IV), chloroplatinic acid, praseodymium(III) hexafluoroacetylacetonate hydrate, dirhenium decacarbonyl, acetylacetonato(1,5-cyclooctadiene)rhodium(I), bis(ethylcyclopentadienyl)ruthenium (II), bis(cyclopentadienyl)ruthenium(II), bis(pentamethylcyclopentadienyl)ruthnenium(II), triruthenium dodecacarbonyl, tris(N,N-bis(trimethylsilyl)amide)samarium(III), tris(tetramethylcyclopentadienyl)samarium(III), tris(2,2,6,6-tetramethyl-3,5-heptanedionato)scandium(III), dimethyl selenide, diethyl selenide, 2,4,6,8-tetramethylcyclotetrasiloxane, dimethoxydimethylsilane, disilane, methylsilane, octamethylcyclotetrasiloxane, silane, tris(isopropoxy)silanol, tris(tert-butoxy)silanol, tris(tert-pentoxy)silanol, (3-aminopropyl)triethoxysilane, N-sec-butyl(trimethylsilyl)amine, chloropentamethyldisilane, hexamethyldisilazane, silicon(IV) chloride, silicon(IV) bromide, pentamethyldisilane, tetraethyl silane, N,N′,N″-tri-tert-butylsilanetriamine, (2,2,6,6-tetramethyl-3,5-heptanedionato)silver(I), triethoxyphosphine(trifluoroacetylacetonate)silver(I), silver(I) triethylphosphine(6,6,7,7,8,8,8-heptafluoro-2,2-dimethyl-3,5-octanedionate), trimethylphosphine(hexafluoroacetylacetonato)silver(I), vinyltriethylsilane(hexafluoroacetylacetonato)silver(I), strontium tetramethylheptanedionate, pentakis(dimethylamido)tantalum(V), tantalum(V) chloride, tantalum(V) ethoxide, tantalum(V) fluoride, tris(ethylmethylamido)tert-butylimido)tantalum(V), tris(diethylamido)(tert-butylimido)tantalum(V), tellurium tetrabromide, tellurium tetrachloride, terbium(2,2,6,6-tetramethyl-3,5-heptanedionate), tris(cyclopentadienyl)terbium(III), tris(tetramethylcyclopentadienyl)terbium(III), thallium(I) ethoxide, thallium(I) hexafluoroacetylacetonate, cyclopentadienylthallium, 2,2,6,6-tetramethyl-3,5-heptanedionatothallium(I), tris(N,N-bis(trimethylsilyl)amide)thulium(III), tris(cyclopentadienyl)thulium(III), tin(IV) chloride, tetramethyltin, tin(II) acetylacetonate, tin(IV) tert-butoxide, tin(II) hexafluoroacetylacetonate, bis(N,N′-diisopropylacetamidinato)tin(II), N,N-di-tert-butyl-2,3-diamidobutanetin(II), tetrakis(dimethylamino)tin(IV), bis(diethylamido)bis(dimethylamido)titanium (IV), tetrakis(diethylamido)titanium (IV), tetrakis(dimethylamido)titanium(IV), tetrakis(ethylmethylamido)titanium (IV), titanium (IV) bromide, titanium (IV) chloride, titanium (IV) fluoride, titanium (IV) tert-butoxide, titanium(IV) isopropoxide, titanium(IV) ethoxide, titanium(IV) methoxide, titanium(IV) isopropoxidebis(2,2,6,6-tetramethyl-3,5-heptanedionate), dichloro titanium(IV) oxide, bis(tert-butylimido)bis(dimethylamido)tungsten (VI), tungsten hexacarbonyl, tungsten (VI) chloride, tungsten (VI) fluoride, triaminetungsten(IV) tricarbonyl, cyclopentadienyltungsten(II) tricarbonyl hydride, bis(isopropylcyclopentadienyl)tungsten(IV) dihydride, bis(cyclopentadienyl)tungsten(IV) dihydride), bis(cyclopentadienyl)tungsten(IV) dichloride, bis(butylcyclopentadienyl)tungsten(IV) diiodide, bis(cyclopentadienyl)vanadium(II), vanadium(V) oxide trichloride, vanadium(V) oxytriisopropoxide, tris(N,N-bis(trimethylsilyl)amide)ytterbium(III), tris(cyclopentadienyl)ytterbium(III), tris(N,N-bis(trimethylsilyl)amide)yttrium (III), yttrium(III) tris(tert-butoxide), yttrium(III) triisopropoxide, yttrium(III) tris(2,2,6,6-tetramethyl-3,5-heptanedionate), tris(butylcyclopentadienyl)yttrium(III), tris(cyclopentadienyl)yttrium(III), yttrium 2-methoxyethoxide, diethylzinc, dimethylzinc, diphenylzinc, bis(2,2,6,6-tetramethyl-3,5-heptanedionate)zinc(II), bis(pentafluorophenyl)zinc, zirconium(IV) dibutoxide(bis-2,4-pentanedionate), zirconium(IV) 2-ethylhexanoate, zirconium tetrakis(2,2,6,6-tetramethyl-3,5-heptanedionate), bis(cyclopentadienyl)zirconium(IV) dihydride, bis(methyl-n-cyclopentadienyl)methoxymethylzirconium, tetrakis(diethylamido)zirconium (IV), dimethylbis(pentamethylcyclopentadienyl)zirconium(IV), tetrakis(dimethylamido)zirconium (IV), tetrakis(ethylmethylamido)zirconium (IV), zirconium (IV) bromide, zirconium (IV) chloride, zirconium (IV) tert-butoxide, and a mixture of any two or more thereof. Precursors for the synthesis of powders and particles, and occasionally for their encapsulation, oftentimes include metal salts and hydroxides, and administered as a dry powder, liquid or gaseous feedstock, or as dissolved in a suitable solvent, via an injection device, nozzle, spray device, vaporizer, sonicator, or other known sub-component to one skilled in the art. Metal salts may be in the form of halides, sulfates, nitritates, oxalates, phosphates, or other inorganic or organic compounds of Ac, Ag, Al, Am, As, At, Au, B, Ba, Be, Bh, Bi, Bk, Br, C, Ca, Cd, Ce, Cf, Cm, Cn, Co, Cr, Cs, Cu, Db, Ds, Dy, Er, Es, Eu, Fe, Fl, Fm, Fr, Ga, Gd, Ge, H, Hf, Hg, Ho, Hs, In, K, La, Li, Lr, Lu, Lv, Mc, Md, Mg, Mn, Mo, Mt, N, Na, Nb, Nd, Nh, Ni, No, Np, O, Og, Os, P, Pa, Pb, Pd, Pm, Po, Pr, Pt, Pu, Ra, Rb, Re, Rf, Rg, Rh, Ru, S, Sb, Sc, Se, Sg, Si, Sm, Sn, Sr, Ta, Tb, Tc, Te, Th, Ti, Tl, Tm, Ts, U, V, W, Y, Yb, Zn, Zr, or combinations thereof.

Additional benefits have been demonstrated on the processing aspects of AM feedstocks. Flowability, compaction uniformity and cohesive powder distribution can play a role in the quality of the AM part, which is typically overcome through the use of higher laser intensity or post-treatment steps to reduce porosity and trapped gas. ALD has been deployed to reduce the cohesion of metal powders, allowing them in some cases to ‘flow like water’, even for 1-5 micron diameter powders. The selection of ALD coating material (e.g. boron nitride) can impart solid lubricating properties onto metallic feedstock powders, which causes better compaction and inherently will lead to a higher density layer at one or more steps in the AM process. A secondary value proposition is that ALD-based solid lubricating coatings allow for the use of more rough, irregular (i.e. non-spheroidized) feedstocks, which can be procured at substantially lower cost than the spherical, monodispersed metal powders required today. In some embodiments, an AM powder feedstock is coated with a secondary phase material that imparts enhanced lubricity, the build density of a workpiece can be increased by 15-25% with no additional post treatments, or conversely, the net energy consumption for post treatment processes carried out on a finished workpiece can be reduced by 20 to 30%.

An additional feature of this technology pertains to the ability to impart air and moisture resistivity for safer handling of Titanium and other pyrophoric or environmentally-sensitive powders. Many studies have been carried out on the oxidation of Titanium and its alloys, but less attention has been paid to the prospective role of the oxidation product as a tribological treatment. A variety of base metals, pyrophoric metal nanoparticles, and environmentally-sensitive powders such as sulfides, have been coated with ALD coatings to impart safety and handling benefits in air or humid conditions. Oxygen in solution with a-Ti produces significant strengthening of the material. The excellent corrosion resistance of titanium under normal conditions is largely due to the formation of very stable, highly adherent and protective titanium dioxide films on the surface. The conventional approach is to carry out simple thermal oxidation steps, in which a native oxide film becomes thicker and tougher with time and/or temperature, thus giving additional protection against corrosion. When titanium and titanium alloys are heated in air at a temperature of 450-800° C. for 2-10 min, protective oxide films exceeding 1 micron can be formed. However, the challenge remains that oxide coatings produced in this manner tend to be quite brittle, so they can be easily damaged by mechanical impact, and provide little improvement in the wear resistance. As such, it was unexpected to find that ultrathin films (<20-30 nanometers) were able to remain mechanically adhered to the surfaces of Ti or Ti-alloy powders, and positively impact the handling of the powders in air, as well as the tribological and mechanical properties (e.g. wear resistance and ductility) of the materials and finished workpieces comprising the materials. Additionally, TGA testing data for Ni nanopowders coated with 5 nm thick aluminum oxide ALD coatings has shown that the oxidation onset temperature of the pristine powders was 300° C., whereas the ALD coated materials did not begin to oxidize until above 700° C. A secondary benefit of ALD coatings can produce AM metal powders that are safe to handle and process without the added costs of high flow rates of inert gas during the printing process. Specifically, secondary phases comprising oxides, nitrides, carbides and halides can be applied to primary powders (e.g. titanium nitride and boron nitride), and more specifically can be deposited on metal and metal alloy feedstock powders comprising titanium, aluminum, nickel, tungsten, cobalt, chromium, iron, vanadium, yttrium, manganese or combinations thereof, enabling AM processing safely without substantial quantities of inert gas flow that is required to prevent the potentially hazardous and exothermic native oxide formation process.

Additionally, it has been unexpectedly found that there is a criticality of ALD thickness, weight loading, crystallinity, grain structure and application sequence of secondary phases that accompanies the rational selection of one or more compounds or materials that comprises said secondary phase. ALD is a relatively simple technique, from the perspective that the self-limiting nature of the “brick-and-mortar” chemistry prevents overbuilding, and the loading on a surface is further constrained by the specific surface area of the substrate materials. Typical growth rates average 0.3 to 2 Å per ALD cycle, depending on coating chemistry, and this level of precise control is critical for optimizing grain size, structure and quantity. A stabilizing ALD coating must be thick enough to provide robustness and stability and thin enough so that the secondary phases maintain an appropriately low, yet specific, thickness and/or weight percent. Additionally, the ideal encapsulation material must be “stable” in the AM process conditions (or alternatively designed for controlled decomposition in the AM process when there is a metallurgical benefit) and should be a proper chemical composition to positively influence the properties of the finished part. ALD is the only technique that can achieve these criteria, and can now be integrated cost-effectively into the AM part supply chain with high-throughput manufacturing systems such as what is described by King et al. in US 20110236575, the content of which, and the content of all references of which, are incorporated herein in their entirety. For example, a stainless steel part derived from a pristine AM feedstock powder was measured to have a specific yield strength, tensile strength, hardness and ductility. When applying a nano-engineered boron nitride coating to the AM feedstock powder and forming a copy exact part, the yield strength and tensile strength could be tuned by 10%, oftentimes 50%, sometimes by 100%, and occasionally by 500%, thereby creating a robust part with one or more enhanced functional benefits. Additional phases and compounds were used to demonstrate that further control over the ductility and hardness is feasible with a properly engineered aggregated secondary phase, which also were able to influence (sometimes upwardly, but occasionally downwardly) other properties already tuned from the thickness, loading or physical or chemical make-up of the secondary phase composition. In one aspect, the present technology allows for the production of highly complex compositions and secondary phases that are homogeneously distributed throughout a produced part with optimal functional characteristics, with the simplicity of being able to pre-load said secondary phases onto feedstock powders prior to incorporation into a part via a powder metallurgy process (or similar particle feedstock fabrication process).

When one or more specific elements selected from the group comprising Ac, Ag, Al, Am, As, At, Au, B, Ba, Be, Bh, Bi, Bk, Br, C, Ca, Cd, Ce, Cf, Cm, Cn, Co, Cr, Cs, Cu, Db, Ds, Dy, Er, Es, Eu, Fe, Fl, Fm, Fr, Ga, Gd, Ge, H, Hf, Hg, Ho, Hs, In, K, La, Li, Lr, Lu, Lv, Mc, Md, Mg, Mn, Mo, Mt, N, Na, Nb, Nd, Nh, Ni, No, Np, O, Og, Os, P, Pa, Pb, Pd, Pm, Po, Pr, Pt, Pu, Ra, Rb, Re, Rf, Rg, Rh, Ru, S, Sb, Sc, Se, Sg, Si, Sm, Sn, Sr, Ta, Tb, Tc, Te, Th, Ti, Tl, Tm, Ts, U, V, W, Y, Yb, Zn, Zr, or combinations thereof, are incorporated in to a nano-engineered secondary phase, there are unique benefits that can be imparted onto a finished part. Benefits may come in the form of reduced processing energy, or number of steps during the fabrication process itself, or any of one or more post-treatments that are required relative to what is required in the absence of one or more nano-engineered secondary phases. Benefits may also come in the form of obtaining a preferential physical or mechanical property of the part that is fabricated when all other process variables are held constant. Benefits may also be in the form of durability and longer useful life of the fabricated part when used in its end-use application. One or more of these or other value propositions can be unlocked or otherwise exploited through the application of the technology as described herein. Substantial benefits have been measured when the primary phase comprises at least one of a solid metal, metal alloy, ceramic, glass and polymer and the secondary phase comprises one or more of a: (i) metal oxide; (ii) metal halide; (iii) metal oxyhalide; (iv) metal phosphate; (v) metal sulfate; (vi) non-metal oxide, (vii) olivine structures, (viii) NaSICON structures, (ix) perovskite structures, (x) spinel structures, (xi) polymetallic ionic structures, (xii) metal organic structures or complexes, (xiii) polymetallic organic structures or complexes, (xiv) structures with periodic properties, (xv) functional groups that are randomly distributed, (xvi) functional groups that are periodically distributed in 2D or 3D periodic arrangements; (xvii) metal nitride; (xviii) metal oxynitride; (xix) metal carbide; (xx) metal oxycarbide; (xxi) non-metallic organic, and (xxii) non-metallic non-organic structures or complexes.

For example, certain combinations of the aforementioned can produce structures used in nuclear reactor design that could someday enable fusion energy as a clean and reliable source of energy. A nano-engineered secondary phase comprising a metal oxide can be combined with a primary phase of an iron-based or ferritic metal or metal alloy to create highly tuned oxide coatings on ferritic oxide dispersion-strengthened (ODS) particles which will improve oxide dispersion in the final sintered composites. Improved homogeneity and uniformity allows for improved material properties such as fracture toughness, but also additional benefits to neutron absorption as an example of application-specific functional benefits that can also be demonstrated, as well as anisotropic behavior resulting from extrusion processes that may be applicable to multiple fields or applications. The materials of construction needed to contain a sustained fusion reaction will be subjected to extremely harsh conditions. The development of improved radiation, corrosion, and heat resistant alloys will have large scale benefits for fusion and Gen III+ fission reactor systems. Additionally, replacing mechanical alloying processes with ALD coatings or other ways to incorporate nano-engineered secondary phases that comprise a homogeneous distribution of materials or compounds will lead to significant improvements in alloy compositions and properties while reducing the production costs. Existing ODS materials have exceptional high temperature creep strength and they show excellent irradiation damage control. An example of a current production methods for ODS alloys involves milling of the metallic phase with nano-powders of the additive oxide phase, typically commercial TiO₂ or Y₂O₃ nanoparticles. The milled mixture is then sintered through extrusion or hot isostatic pressing. For this application, a fully homogeneous dispersion of the oxide phase within the metal matrix (and preferably the homogeneous distribution of the components of the entire secondary phase) protects against neutron degradation. This phenomenon allows the alloys to maintain appropriate mechanical properties much longer than conventional alloys subjected to high amounts of radiation damage. Maximizing the uniformity of the secondary phase dispersion also leads to better performance by reducing defect migration distances within the bulk material. Fusion reactors will create higher neutron radiation levels and require materials that stay in service for extended periods of time under dosing levels as high as 200 dpa. The existing production methods are severely limited by i) the amount of oxide they can add to the alloy; ii) how well the oxide can be dispersed before grain size and oxygen/nitrogen incorporation become detrimental to the material performance; iii) how much the secondary phase can be nano-engineered; and iv) how uniform and homogeneous the dispersion can be maintained over parts of varying sizes and produced using an array of approaches that use particles as a feedstock.

For applications or processes that incorporate nanoparticles or other secondary phases using milling or high energy mixing processes, the incorporation of impurities on the parts per million level or higher is insurmountable and detrimental for several reasons. First, as milling time is increased, the incorporation of impurities into the matrix increases. These impurities can be contaminants form the milling media and components, or the addition of oxygen, carbon dioxide and nitrogen in air environments, or other constituent materials from alternate environments. The addition of increased oxygen as a contaminant is detrimental to some material properties of the alloy, but the addition of the secondary oxide phases improves the overall mechanical strength of the material. As the target oxide loading in the secondary phase is preferentially increased, the mixing and/or milling time must be increased to homogeneously distribute said oxide. Thus with the milling procedures currently practiced in the art, the practical limits for oxide addition and improvements are counteracted by the incorporation of additional oxygen during the extended milling process.

The second limitation caused by milling is the change in crystallite size. Large amounts of mechanical work is applied to the materials as they are milled. This work reduces particle sizes but also changes the crystallite size and structure, which can be further exacerbated by parts per million of contamination from the milling media itself. This reduces the amount of process control a manufacturer can have on both the feedstock materials as well as the fabricated part. Additionally, this effect can also require significant heat treatment and recrystallization post processing that can at minimum add cost, and add the unnecessary risk of precipitation and/or coalescence of the oxide phase towards grain boundaries, thus reducing the homogeneity. The final drawback to using mechanical milling process to disperse oxide particles are the inherent size limitations. Typical commercial oxide powders used in milling on the order of 20-50 nanometers and are not engineered or otherwise designed for the general field or application described herein. Not only are these sized particles expensive, but they are difficult to properly handle safely and physically inter-mix with the primary particle phase. Milling can reduce the oxide particle size further but, as previously discussed, there are limits to the amount of time milling can be conducted. This leaves oxide particles that are routinely found to be in the 10 to 20 nanometer size range. When the material is extruded these particles turn into elongated defects that are directionally oriented parallel to the extrusion direction, and when cast or molded, result in discrete phases that are randomly (i.e. not homogeneously) distributed and exceed the optimal grain size that can be targeted through the practicing of this invention. Ultimately, this leads to significant material anisotropies that limit the uses of these materials.

By eliminating or significantly altering the milling process described in the art that is currently used in the fabrication of ODS steels, many of the described drawbacks can be eliminated. By incorporating a nano-engineered and highly controllable oxide coating process, existing alloy performance can be improved and the creation of new alloys will lead to material property enhancements that can accommodate the harsh conditions required for Fusion reactor materials and enable many other applications for nano-engineered composites. The discussion on ODS steels is meant to serve as an exemplary application of the technology described herein and is not intended to limit the applicability or scope to other primary phases (non “steel” materials) or secondary phases (non “oxide” materials); examples of such would include: nitride dispersion strengthened materials; aluminum or titanium alloy primary phases; halide, phosphate and/or borate strengthened metals, alloys or glasses; ceramic strengthened polymers; polymer-derived ceramic incorporated onto metals ceramics or glasses; and so on. The ability to nano-engineer a homogeneous secondary phase, which may comprise a specific composition, loading or sequence of materials, processes or steps, can provide a direct functional benefit to primary phases of any material, thereby making a measurably higher performance nano-engineered composite when fabricated into a workpiece using any number of fabrication processes that utilize powder-based feedstocks. In particular, AM feedstock materials that incorporate nano-engineered secondary phases produced using specific ALD processes will produce fully homogeneous finished parts that exhibit more useful properties than such a workpiece produced that does not have a nano-engineered secondary phase.

A workpiece of the present technology may be exceptionally-suited for use in a variety of applications, which at minimum would be better-suited for use than a comparative workpiece that does not utilize the nano-engineered feedstock or feedstocks of the present technology. Relevant applications that should in no way be considered limiting include: i) structural or containment members for nuclear applications; ii) as an anode, anolyte, cathode, catholyte, electrolyte, current collector, stack member, electrode assembly, separator, membrane, or as a pack member of an electrochemical cell, comprising one or more of a battery, capacitor, electrolyzer, liquid-based fuel cell or a solid oxide fuel cell; iii) configured for general use as a structural member, for example in construction or other building projects; iv) configured for use as an armor or shielding member (physical, chemical or electrical shielding/protection) on a mobile or stationary device, for military and civilian purposes; or v) configured for use as a lightweighting means for a stationary or motive/mobility application.

A key feature of the ability to add nanostructured phases within AM-derived parts that are fabricated on a layer-by-layer basis in the Z-direction is that the anisotropy that is typically inherent to such production methods can be minimized or eliminated. It has been discovered that the enhanced joining and improved interparticle welding feature of the invention not only improve the bulk mechanical (and other) properties of finished workpieces, but also since each layer that is applied in the construction direction comprises multiple sub-layers of nanostructured phases, the finished parts tend to have much lower degree of anisotropy, particularly in the Z-direction. Workpieces produced that comprise the inventive particles can be constructed with higher aspect ratios without adversely impacting properties and can be built taller and faster based on the inclusion of highly functional secondary phases.

In furtherance of the aforementioned improvement to anisotropy, another benefit to functionalized powders with enhanced flowability is that thicker powder layers can be used without sacrificing as built or finished workpiece quality or yields, leading to a more rapid process to produce discrete parts.

In some embodiments, the composition and amount of secondary phase material (e.g. thickness in case of a coating) is selected in order to maximize the uniformity of interactions between a laser beam and powder particles. In practice, standardizing absorption, reflection and scattering has also allowed for wider particle size distributions and more irregular particles to be used without sacrificing as built or finished workpiece quality or yields.

As with any industrially-minded process development, ways in which AM fabrication step speed can be increased or number of steps reduced, would be valuable to the industry. As such, it has been unexpectedly observed that simply by i) enabling an increased stripe width; ii) enabling an increased hatching space between adjacent scan tracks; and/or iii) reducing overlap required for neighboring stripes with uniform coatings without adversely impacting mechanical properties of produced workpieces can greatly improve overall productivity and reduce costs. In some embodiments, by incorporating a beneficial secondary phase material, such productivity developments can be effectuated to reduce overall costs while increasing end-use performance.

In at least one embodiment, it has been shown that defects in produced workpieces (e.g. microporosity, microcracks, etc.) can be reduced by optimizing key-hole beam-weld interaction, gas distribution or enhanced removal during processing, controlled or otherwise uniform shrinkage between layers, etc. Particularly in embodiments that comprise ALD-enabled metal or metal alloy powders, which have significantly improved creep strength, ductility, toughness (particularly impact toughness) and fatigue life. Post-processing using Hot Isostatic Pressing (HIP) can be performed at reduced pressures, temperatures or times as the degree of segregation due to a more homogeneous microstructure in as-built parts, and fewer residual stresses.

Oftentimes, blends of powders are produced prior to being fed into an AM process, which within a powder could be described as a primary and secondary phase based upon loading considerations. However, the intended functionalized powder is a primary particle having secondary particles adhered to a majority of the external surfaces. There are many challenges associated with creating this type of system. First, is that van der Waals forces must be sufficient to allow the secondary phase particles to stick to the surfaces of the primary powder feedstock materials, and secondary phase particles would be small and primary phase particles would be large. Second, it is oftentimes an insurmountable challenge to de-agglomerate secondary phase particles such that the adhering particles upon re-agglomerating to the primary phase particles only form as uniform of a layer as possible. A simultaneous challenge is to have a secondary phase particle feedstock with a sufficiently narrow, ideally monodisperse, size distribution, while remaining small enough to allow van der Waals forces to dominate. Though this is remotely possible, ALD can be used here as an alternative to applying ceramic reinforcement nanopowders onto, for example, metal or metal alloy matrix powders, thereby creating a composite powder ready for AM. Surface coatings obviate the need to restrict available material sets and classes to ones that can obtained in powder form while overcoming the constraints described herein. A hybrid approach is also of interest to enjoy the benefits of both approaches, which is to create a secondary material phase comprising multiple sub-phases, of which one may be a blend-able powder substrate, and one may be derived using an ALD coating to facilitate a more robust attachment of an adhered particle phase. Such a composite powder is achievable using the present technology. In some embodiments, boron or silicon nitride powders are physically blended with metal alloy feedstock powders, and the materials are then loaded into an ALD reactor to apply a ceramic overcoating to the composite powders. In specific embodiments, aluminum and titanium AM feedstock powders were individually blended with silicon nitride powders, upon which aluminum oxide ALD coatings were applied. Each set of powders was printed into dogbone-type workpieces. Upon characterizing the chemical composition of each, it became evident that in addition to the primary phase of either aluminum or titanium, a secondary phase of each type of workpiece comprised a ‘SiAlON’ material, or silicon aluminum oxynitride. Such a material is known to impart strength and mechanical property advantages to finished workpieces. In one aspect, the present technology provides the ability to rationally design the primary and secondary phases to maximize the quality of finished workpieces, while minimizing production time and costs.

In another aspect, the present technology provides the ability to design secondary phase coatings that improve the health, safety and environmental issues with conventional metal powders via improved handling; increasing shelf-life of metal powders due to improved corrosion resistance. Additionally, it is difficult for some materials to be re-used after being run through PM processes, but which fall outside of the finished workpiece as unused material. An example of this is the powder contained within a powder bed of an AM printing tool. Excess materials can be reused, to an extent, but feedstock powders having ALD corrosion resistance coatings can be reused for two to three times the number of passes as feedstock powders devoid of surface coatings. Ultimately, an ability to enhancing the recycling or reusability of powdered feedstock materials after being processed through AM cycles, will reduce the total ascribed costs per produced workpiece.

In some embodiments, the present technology can enable the use of smaller powder feedstock particle sizes, or the strategic use of a bimodal distribution of powder feedstock particle sizes, for secondary phase materials that provide enhanced lubricating properties while overcoming any propensity toward oxidation. For example, AM feedstock powders typically have a mean particle diameter in the 40-50 micron range. It has been observed that smaller primary particles of the same substrate material, having secondary material phases in the form of coatings, can be incorporated in with larger primary phase particles and fill void spaces. Such a means of regularizing the interstitial packing, has shown to improve the mechanical properties of finished workpieces.

In one aspect, the present technology provides reduction in the primary phase material vaporization in the presence of excessive energy. This provides an opportunity for the construction of high value products that are difficult, costly or cumbersome to produce today, including: solid state batteries, catalyst surfaces and catalytic converters with optimized geometries, advanced motor designs that can be optimized for use with high temperature stabilized permanent magnets, amongst others. Additionally, inventive workpieces can be produced from non-traditional primary particle feedstocks that have nanostructured secondary phases that allow for the use of such materials. For example, exotic metals such as precious metals, platinum group metals, refractory metals, low vaporization temperature metals, etc., can now be incorporated in additively manufactured workpieces, wherein either the primary phase or the secondary phase (or phases) can comprise said materials, depending on the form, function and application of the workpiece. One such application is the fabrication of workpieces for particle accelerator components, in which exotic metal powders can be configured for use in Binder Jetting, Direct Metal Laser Sintering, or Bound Metal Deposition 3D printers via incorporation of specific secondary phases. In general, many components used in applications that are considered niche, or will inherently have small volume manufacturing requirements due to limited demand, may benefit from being produced from exotic metals for various physics and engineering reasons. An example is the use of niobium for superconducting RF cavities and ancillary components. Additively manufacturing these workpieces allows complex geometries to be fabricated easily and quickly, but many of the exotic materials are not available for printing yet. Binder Jetting and Bound Metal Deposition printers offer a relatively low cost of entry into metal 3D printing, and use standard Metal Injection Molding (MIM) powders as feed material. Direct Metal Laser Sintering (DMLS) printers cost more, and utilize special uniform grain size powders as their feed material. In one aspect, the present technology provides development and realization of exotic metal powders (such as niobium), which can be rendered suitable for printing in any of the aforementioned processes, and allowing for more exotic materials to become an option for the production of complex components such as what are used in accelerators.

Analogously, detectors for particle physics need exquisite performance and need to be composed of materials that have to withstand harsh conditions, such as ultra-cold, high pressure or high-radiation environments. Workpieces relevant to this field, such as sensors and detectors, are often characterized by having large areas or large volumes. As such, with higher localized uniformity in the melting of powders within each additive manufacturing layer, and more homogeneous joining of successive layers, more homogeneous mechanical properties can be demonstrated in the X, Y and Z directions, allowing for greater cross-workpiece uniformity. This enhanced cross-workpiece uniformity in turn provides an opportunity to produce larger and larger components with additive manufacturing techniques (e.g. wind turbine blades or large objects with complex, precision geometries). The enhanced uniformity in all directions also has been demonstrated to reduce the surface roughness of as-built workpieces (to less than 25 microns), at locations that are millimeters, oftentimes centimeters, sometimes decimeters and occasionally meters apart from one another. This enhanced uniformity also minimizes residual stresses in as-built parts, which leads to a measurable reduction in thermal stress, fatigue and warping in finished parts.

1-17. (canceled)

18. An additive manufacturing powder comprising particles, comprising: a titanium metal core and an alumina coating having a thickness of between 3 and 30 nm.

19. The alumina coating of claim 18 having a thickness of 3 to 20 nm.

20. The alumina coating of claim 18 having a thickness of 3 to 5 nm.

21. A method of making the particles of claim 18, comprising applying the alumina coating by ALD.

22. Forming a workpiece by additive manufacturing using the powder of claim 18.

23. An additive manufacturing powder comprising particles, comprising: a metal core and a BN coating, wherein the particles have a 1- to 5-micron diameter.

24. Forming a workpiece by additive manufacturing using the powder of claim 23.

25. An additive manufacturing powder comprising Al or Ti particles blended with SiN particles; wherein the Al or Ti particles and the SiN particles comprise alumina ALD coatings applied to the Al or Ti particles and the SiN particles.

26. Forming a workpiece by additive manufacturing using the powder of claim 25.

27. A workpiece formed by additive manufacturing using the powder of claim 25.

28. A workpiece comprising a primary phase comprising Al or Ti and a secondary phase comprising silicon aluminum oxynitride.
